(19) United States
(12) Patent Application Publication
(10) Pub. No.: US 2005/0269677 A1
(43) Pub. Date: Dec. 8, 2005

(54) Preparation of front contact for surface mounting

(76) Inventors: Martin Standing, Tonbridge (GB); Andrew Sawle, West Sussex (GB); David P. Jones, South Glamorgan (GB); Martin Carroll, Canton (GB); Matthew Elwin, Sketty (GB)

Correspondence Address: OSTROLENK FABER GERB & SOFFEN, 1180 AVENUE OF THE AMERICAS, NEW YORK, NY, 100368403, US

(21) Appl. No.: 11/138,141

(22) Filed: May 26, 2005

Related U.S. Application Data
(60) Provisional application No. 60/575,656, filed on May 28, 2004.

(51) Int. Cl. H01L 23/02

(52) U.S. Cl. 257/678

(57) ABSTRACT

A semiconductor device which includes a power electrode on a surface thereof, a solderable body on the power electrode and a passivation body spaced from but surrounding the solderable body.

### RELATED APPLICATION

This application is based on and claims benefit of U.S. Provisional Application No. 60/575,656, filed on May 28, 2004, entitled Preparation of Front Contact for Surface Mounting, to which a claim of priority is hereby made and the disclosure of which is incorporated by reference.

### BACKGROUND OF THE INVENTION

The present invention relates to semiconductor devices.

Chip-scale packaging is a concept driven by the idea of devising a semiconductor package which is nearly the size of the die contained therein. U.S. Pat. No. 6,624,522 illustrates several chip-scale packages, each of which includes a power semiconductor die, such as a power MOSFET, with at least one power electrode configured for direct electrical and mechanical connection to conductive pads on a substrate, such as a circuit board, by a conductive adhesive body such as solder, conductive epoxy or the like.

To facilitate such a direct connection a solderable body is formed on the power electrode in contact with a passivation body, which itself resides over the power electrode. It has been found that some metals in the solderable body, such as, silver, form dendrites after a period of use. The dendrites damage the passivation body, and in some cases may undesirably short the power electrode to a nearby conductive body. For example, in a power semiconductor package having a die disposed within a conductive clip, the dendrites may grow long enough to short the power electrode to the conductive clip. This condition may be worse when the conductive clip also includes a metal that exhibits a tendency to form dendrites, such as silver.

It is desirable to avoid the damage in order to ensure longer service life for the power semiconductor device.

### SUMMARY OF THE INVENTION

In a device according to the present invention a gap exists between the passivation and the solderable body in order to prevent the formation of dendrites, and thus improve the service life of the device.

Specifically, a semiconductor device according to the present invention includes a semiconductor die having one side thereof configured for direct connection to a conductive pad with a conductive adhesive, the one side including at least one power electrode, a passivation body formed on the at least one electrode, an opening in the passivation body exposing the at least one electrode, a solderable body formed on the at least one electrode, the solderable body being less wide than the opening whereby a gap exists between the passivation and the solderable body.

The preferred embodiment of the present invention includes:
a semiconductor die having a first major surface and an opposing second major surface; a first power electrode on the first major surface having at least one solderable body formed on a portion thereof; a control electrode on the first major surface having at least one solderable body formed on a portion thereof; and a passivation body formed on the first power electrode and including an opening to expose the at least one solderable body on the first power electrode, the opening being wider than the at least one solderable body whereby the at least one solderable body is spaced from the passivation by a gap which surrounds the at least one solderable body on the first power electrode.

Other features and advantages of the present invention will become apparent from the following description of the invention which refers to the accompanying drawings.

### BRIEF DESCRIPTION OF THE FIGURES

FIG. 1 shows a top plan view of a semiconductor device according to the first embodiment of the present invention.

FIG. 2 shows a cross-sectional view of a device according to the first embodiment of the present invention along line 2-2 and viewed in the direction of the arrows.

FIG. 3 shows a top plan view of a semiconductor device according to the second embodiment of the present invention.

FIG. 4 shows a top plan view of a semiconductor device according to the third embodiment of the present invention.

FIG. 5 shows a top plan view of a package according to the present invention.

FIG. 6 shows a bottom plan view of a package according to the present invention.

FIG. 7 shows a cross-sectional view of a package according to the present invention along line 7-7 and viewed in the direction of the arrows as mounted on conductive pads of a substrate.

FIG. 8 shows a top plan view of a wafer having a plurality of die.

FIG. 9 shows a top plan view of a wafer having a plurality of die after electrodes have been formed thereon.

FIG. 10 shows portions 5-5 of the wafer in FIG. 4 after formation of a plurality of solderable layers.

FIG. 11 shows portion 5-5 after formation of a passivation.

FIG. 12 shows portion 5-5 of the wafer after openings have been formed in the passivation over each solderable layer.

### DETAILED DESCRIPTION OF THE EMBODIMENTS OF THE INVENTION

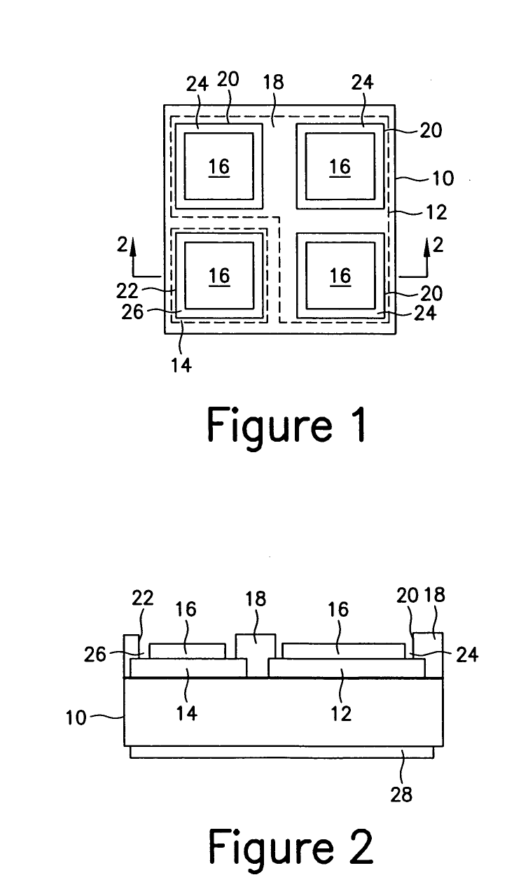

Referring to FIGS. 1 and 2, a semiconductor device according to the present invention includes a semiconductor die 10 having first power electrode 12 and control electrode 14 on a first major surface thereof.

According to a first embodiment of the present invention at least one solderable body 16 is formed on first power electrode 12 and at least one solderable body 16 is formed on control electrode 14. Furthermore, in a device according to the present invention, a passivation body 18 which is formed preferably from an epoxy that can also function as a solder resist, is disposed on first power electrode 12 and control electrode 14, and includes opening 20 to expose solderable body 16 on first power electrode 14 and opening 22 to expose solderable body 16 on control electrode 14. In the preferred embodiment, electrodes 12, 14 are formed from aluminum or aluminum silicon, and solderable bodies 16 are formed from a trimetal stack or any solderable material that may tend to form dendrites. The trimetal stack may include a silver layer at the top thereof, such as Ti/Pd/Ag trimetal stack.

According to an aspect of the present invention, opening 20 is wider than solderable body 16. As a result, solderable body 16 is spaced from passivation 18 by a gap 24 which surrounds solderable body 16. It should be noted that in the preferred embodiment, opening 22 is also wider than solderable body 16 on control electrode 14 whereby gap 26 is created between passivation body 18 and solderable body 16 on control electrode 14.

In the preferred embodiment, passivation body 18 includes a plurality of openings 20 each being wider than and exposing a respective solderable body 16 on first power electrode 12 whereby a respective gap 24 is formed between each solderable body 16 and passivation body 18. Also, in the preferred embodiment, passivation body 18 is thicker than solderable bodies 16. As a result, solderable bodies 16 do not extend beyond passivation body 18. That is, each solderable body 16 is preferably disposed at the bottom of its respective opening 20 and does not reach the top thereof.

A semiconductor device according to the embodiment shown by FIGS. 1 and 2 can be of a vertical conduction variety and thus includes second power electrode 28 on second major surface thereof opposite to the first major surface. For example, a device according to the embodiment shown by FIGS. 1 and 2 can be a power MOSFET in which first power electrode 12 is the source electrode, second power electrode 28 is the drain electrode, and control electrode 14 is the gate electrode.

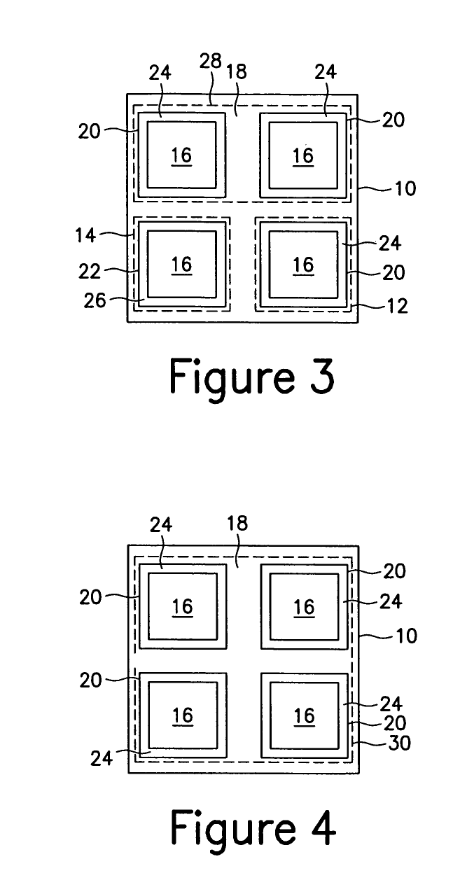

A device according to the present invention is not limited to vertical conduction type devices. Referring to FIG. 3, in which like numerals identify like features, a device according to the second embodiment may be of the flip-chip variety, in which case first power electrode 12, second power electrode 28, and control electrode 14 are disposed on a common surface of die 10. A device according to the second embodiment may be a power device such as a power MOSFET, in which case first power electrode 12 is the source electrode, second power electrode 28 is the drain electrode and control electrode 14 is the gate electrode.

Referring next to FIG. 4, in which like numerals identify like elements, a semiconductor device according to the third embodiment includes only a single power electrode 30 on a major surface thereof, and unlike the first embodiment and the second embodiment does not include a control electrode. A device according to the third embodiment can be, for example, a vertical conduction type diode in which one of its power electrodes (i.e., either the anode electrode or the cathode electrode) includes passivation body 18 on a surface thereof with openings over solderable bodies 16, in each opening being wider than a respective solderable body 16 that it surrounds and passivation 18 being preferably thicker than solderable bodies 16.

All three embodiments are similar in that in each case all of the electrodes on one side are configured for direct connection with a conductive adhesive such as solder or conductive epoxy to a conductive pad on a substrate such as a circuit board. That is, solderable bodies 16 are provided on all electrodes on the same surface to allow for direct connection to a conductive pad on a substrate, while advantageously a gap 24 between each solderable body 16 and passivation body 18 prevents the formation of dendrites.

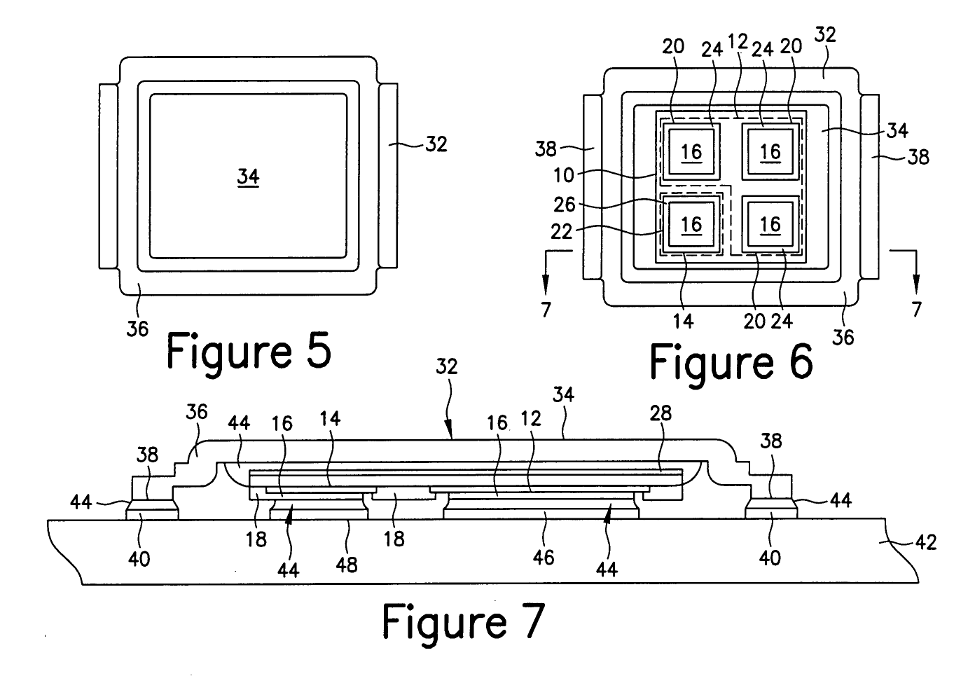

Referring next to FIGS. 5, 6 and 7, a semiconductor device according to the present invention can be packaged using a conductive clip 32 according to the concept shown by U.S. Pat. No. 6,624,522. For example, a semiconductor device according to the first embodiment can have its second power electrode 28 electrically connected to the web portion 34 of a cup-shaped or can-shaped conductive clip 32 by a conductive adhesive 44 such as solder or conductive epoxy. Thus, conductive clip 32 can act as an electrical connector for external electrical connection to second power electrode 28.

Conductive clip 32 is preferably made from copper or an alloy of copper and may include gold or silver on its exterior surface. Preferably, conductive clip 32 includes a rim 36 which is integral with web portion 34 and defines an interior space within which a semiconductor device according to the present invention is received. Note that rim 36 acts as an electrical connector between web portion 34 (which is electrically connected to second power electrode 28) to preferably two terminal connection surfaces 38. Connection surfaces 38 serve to electrically connect conductive clip 32 to conductive pads 40 on a substrate 42 such as a circuit board. Note that connection surfaces 38 are electrically connected to pads 40 by a conductive adhesive 44 such as solder or a conductive epoxy. Also, as explained above, a semiconductor device according to the present invention is configured in order to have the electrodes on one side thereof directly electrically connected to the conductive pads of a substrate. Thus, as seen in FIG. 7, first power electrode 12 is electrically connectable to a respective conductive pad 46 by a conductive adhesive 44 such as solder or a conductive epoxy, and control electrode 14 is similarly electrically connectable to a respective conductive pad 48 on substrate 42.

A semiconductor device according to the present invention may be manufactured according to the following process.

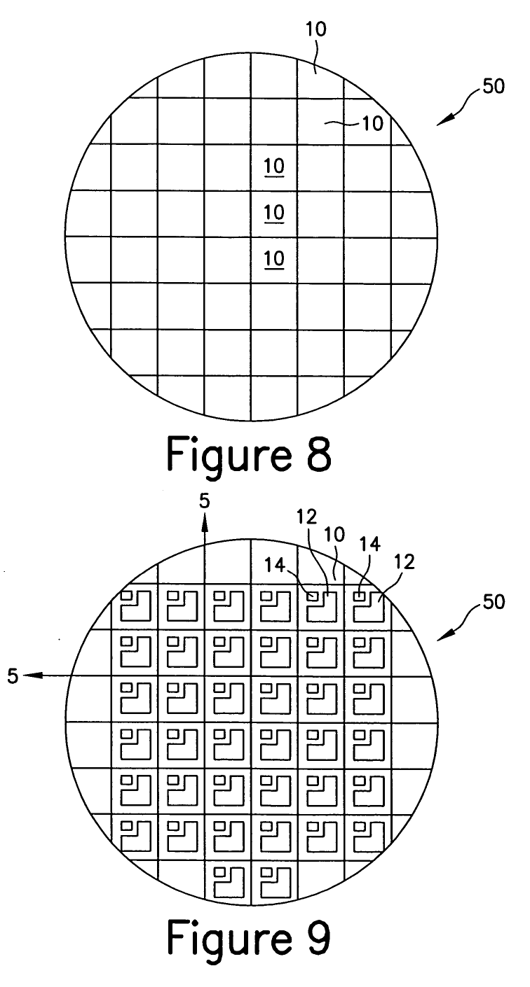

Referring to FIG. 8, first a plurality of die 10 are formed in a wafer 50 in a conventional manner. Thus, for example, in the preferred embodiment, a plurality of vertical conduction type power MOSFETs are formed in any known manner in a silicon wafer.

Next, a contact metal layer is deposited and patterned in any known conventional manner. Thus, in the preferred embodiment a front metal layer is deposited over wafer 50 in which the MOSFETs are formed, and patterned to form first power electrode 12 (hereafter source contact or source electrode) and control electrode 14 (hereafter gate contact or gate electrode) for each die 10 as shown by FIG. 4. A suitable front metal for this purpose may be Al or AlSi.

Next, a solderable front metal is deposited over the contact metal layer. The solderable front metal may be any suitable metal combination such as the trimetal combination Ti/Pd/Ag. In the preferred embodiment, the solderable front metal layer includes a top layer of silver.

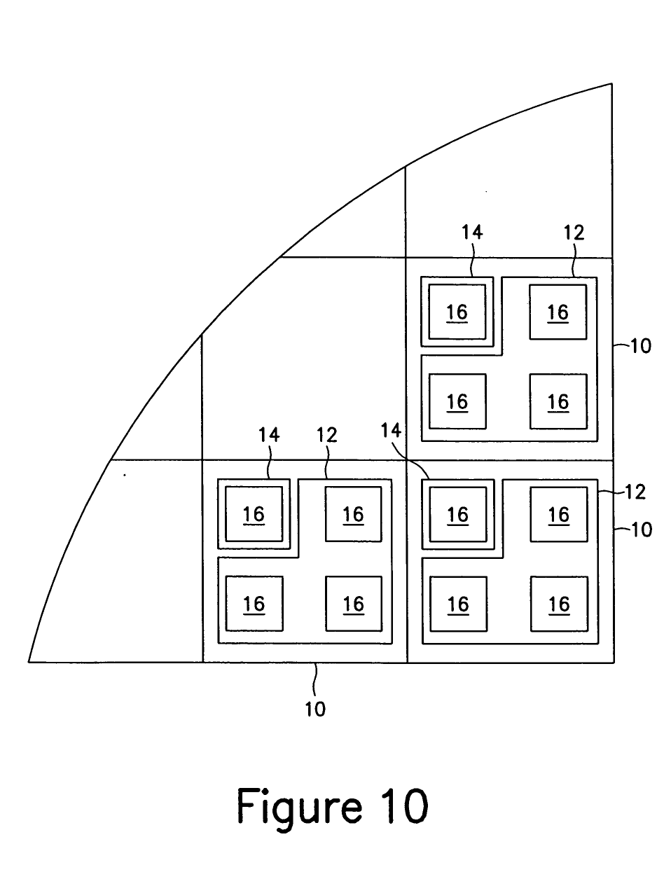

Thereafter, the solderable front metal layer is patterned leaving at least one solderable body 16 over each contact e.g., source contact 12, as illustrated by FIG. 10. Thus, in the preferred embodiment, the solderable front metal is patterned to result in at least one solderable body 16 on gate electrode 14 and source electrode 12, or preferably a plurality of solderable bodies 16 over source electrode 12.

Thereafter, a back metal contact (not shown) is deposited over the back of the wafer 24 if such is required for a second power electrode for each die. Thus, for example, in the preferred embodiment, a drain back metal is formed in the back of the wafer. The drain back metal may be formed of Al or AlSi and further processed to include a solderable trimetal combination.

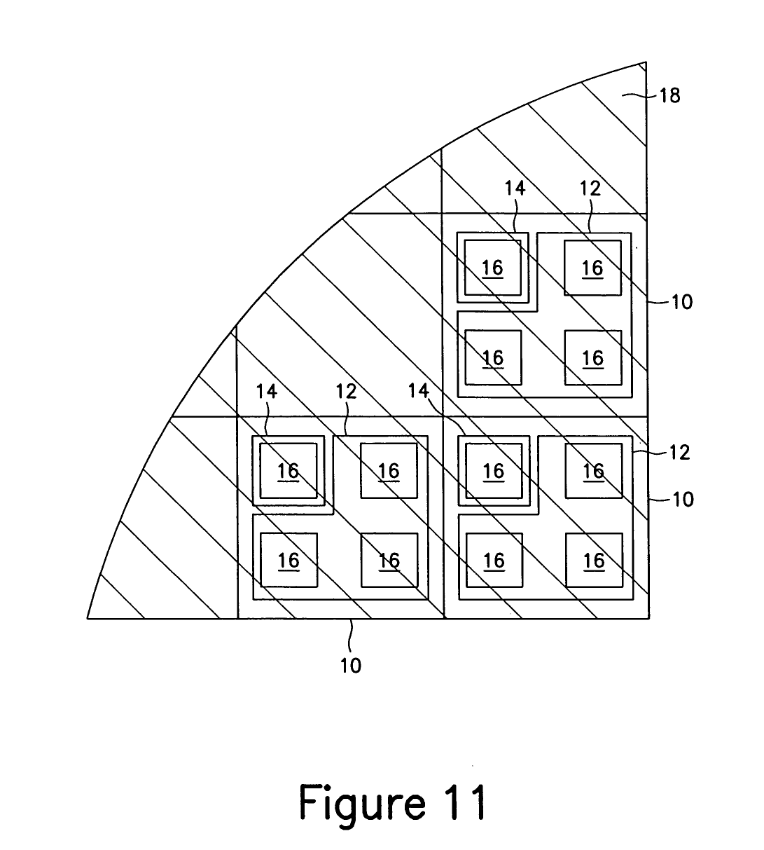

Next, a passivation body 18 is formed over the front side of wafer 50 as illustrated in FIG. 11 by slanted lines. Passivation body 18 may be any suitable epoxy passivation which may also be able to act as a solder resist. The epoxy passivation may be screen printed. Thus, in the preferred embodiment, a suitable epoxy passivation may be formed over source electrodes 12 and gate electrodes 14.

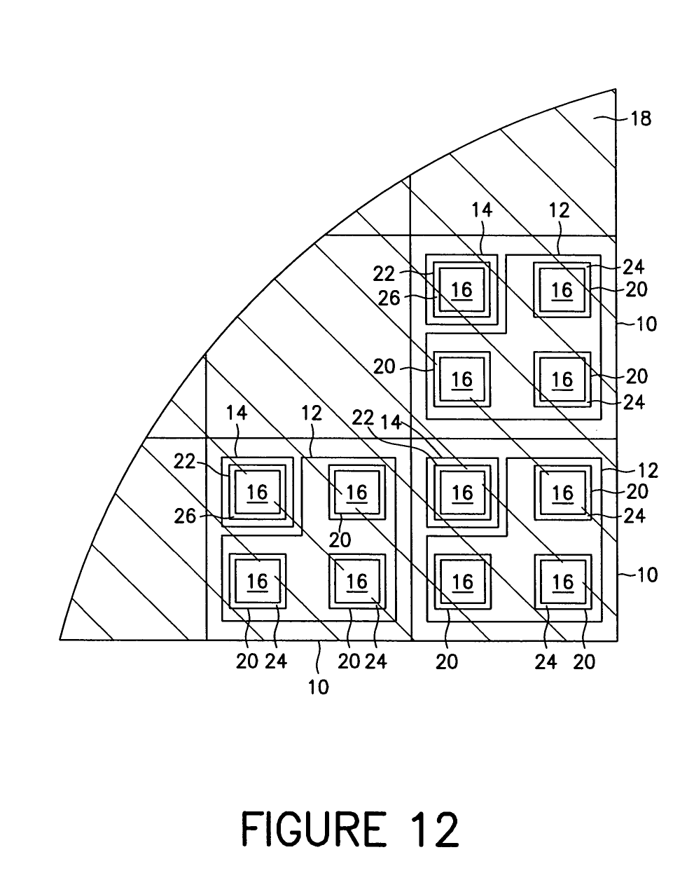

Thereafter, passivation 18 is removed from the top of each solderable body 16 over each contact. The removal of passivation 18 creates openings 20, 22 that extend to the contact layer below. Thus, in the preferred embodiment of the present invention, an opening is created in passivation 18 over each source electrode 12 and an opening is created over gate electrode 14 exposing respective solderable bodies thereon as seen in FIG. 12.

According to an aspect of the present invention openings 20 and preferably openings 22 are created wide enough so that each solderable body 16 may be spaced from passivation 18 by a respective gap.

Next, each die is singulated by any known method, such as sawing. Each singulated die may then be packaged in a conductive clip 32 to obtain a semiconductor package as described herein.

Although the present invention has been described in relation to particular embodiments thereof, many other variations and modifications and other uses will become apparent to those skilled in the art. It is preferred, therefore, that the present invention be limited not by the specific disclosure herein, but only by the appended claims.

1. A semiconductor device comprising:
a semiconductor die having a first major surface and an opposing second major surface;
a first power electrode on said first major surface having at least one solderable body formed on a portion thereof;
a control electrode on said first major surface having at least one solderable body formed on a portion thereof; and
a passivation body formed on said first power electrode and including an opening to expose said at least one solderable body on said first power electrode, said opening being wider than said at least one solderable body whereby said at least one solderable body is spaced from said passivation by a gap which surrounds said at least one solderable body on said first power electrode.

2. A semiconductor device according to claim 1, wherein said passivation body includes another opening to expose said at least one solderable body on said control electrode.

3. A semiconductor device according to claim 1, further comprising a plurality of solderable bodies formed on said first power electrode, and a plurality of openings in said passivation body each said opening exposing a respective solderable body on said first power electrode, and being wider than said respective solderable body whereby said respective solderable body is spaced from said passivation by a gap which surrounds said respective solderable body on said first power electrode.

4. A semiconductor device according to claim 1, wherein said passivation body is thicker than said at least one solderable body on said first power electrode whereby said at least one solderable body does not extend beyond said passivation body.

5. A semiconductor device according to claim 1, wherein said at least one solderable body on said first electrode includes silver.

6. A semiconductor device according to claim 1, wherein said at least one solderable body on said first electrode is comprised of a solderable trimetal, a top portion of said trimetal being composed of silver.

7. A semiconductor device according to claim 1, further comprising a second power electrode on said second major surface, and a conductive clip, said second power electrode being electrically connected to said conductive clip by a conductive adhesive.

8. A semiconductor device according to claim 7, wherein said conductive clip includes silver on an exterior surface thereof.

9. A semiconductor device according to claim 7, wherein said conductive clip is cup-shaped.

10. A semiconductor device according to claim 1, further comprising a second power electrode on said first major surface, and at least one solderable body on said second power electrode; wherein said passivation includes an opening to expose said solderable body on said second electrode being wider than said at least one solderable body whereby said at least one solderable body on said second power electrode is spaced from said passivation by a gap which surrounds said at least one solderable body on said second power electrode.

11. A semiconductor device according to claim 1, wherein said semiconductor die is a power MOSFET, said first power electrode is a source electrode and said control electrode is a gate electrode.

12. A semiconductor device according to claim 1, wherein said passivation is comprised of epoxy-based passivation.

13. A semiconductor device comprising:
a semiconductor die having one side thereof configured for direct connection to a conductive pad with a conductive adhesive, said one side including at least one power electrode, a passivation body formed on said at least one electrode, an opening in said passivation body exposing said at least one electrode, a solderable body formed on said at least one electrode, said solderable body being less wide than said opening whereby a gap exists between said passivation and said solderable body.

14. A semiconductor device according to claim 13, wherein said one side further includes a control electrode, and a solderable body formed over said control electrode, wherein said passivation body includes an opening exposing said solderable body on said control electrode.

15. A semiconductor device according to claim 13, wherein said one side further include another power electrode, and a solderable body on said another power electrode, wherein said passivation body includes an opening exposing said solderable body on said another power electrode, said solderable body being less wide than said opening whereby a gap exists between said passivation and said solderable body on said another power electrode.

16. A semiconductor device according to claim 13, wherein said semiconductor die is a diode.

17. A semiconductor device according to claim 13, wherein said semiconductor die is a power MOSFET.

18. A semiconductor device according to claim 13, further comprising a plurality of solderable bodies on said at least one power electrode and spaced from one another, wherein said passivation includes a plurality of openings each being wider than and exposing a respective solderable body whereby a gap exists between each respective solderable body and said passivation.

19. A semiconductor device according to claim 13, wherein said solderable body includes silver.

20. A semiconductor device according to claim 13, wherein said passivation is comprised of an epoxy.
